(19) United States
(12) Patent Application Publication
(10) Pub. No.: US 2012/0038042 A1
(43) Pub. Date: Feb. 16, 2012

(54) LEAD-FREE SOLDER ALLOY, SOLDER BALL, AND ELECTRONIC MEMBER COMPRISING SOLDER BUMP

(75) Inventors: Tsutomu Sasaki, Tokyo (JP); Shinichi Terashima, Tokyo (JP); Masamoto Tanaka, Tokyo (JP); Katsuichi Kimura, Saitama (JP)

(73) Assignees: Nippon Micrometal Corporation, Saitama (JP); Nippon Steel Materials Co., Ltd., Tokyo (JP)

(21) Appl. No.: 13/264,625

(22) PCT Filed: Apr. 12, 2010
(86) PCT No.: PCT/JP2010/056521

§ 371 Date: Oct. 14, 2011

(30) Foreign Application Priority Data
Apr. 14, 2009 (JP) 2009-097647

(51) Int. Cl. H01L 23/498; C22C 13/02; C22C 30/02; C22C 30/04; C22C 13/00

(52) U.S. Cl. 257/737; 420/589; 420/557; 420/560; 420/587; 420/562; 257/E23.068

(57) ABSTRACT

A lead-free solder alloy, a solder ball and an electronic member comprising a solder bump which enable the prevention of the occurrence of yellow discoloration on the surface of a solder after soldering, the surface of a solder bump after the formation of the bump in a BGA, and the surface of a solder bump after a burn-in test of a BGA. Specifically disclosed are: a lead-free solder alloy; a solder ball; and an electronic member comprising a solder bump, containing at least one additive element selected from Li, Na, K, Ca, Be, Mg, Sc, Y, lanthanoid series elements, Ti, Zr, Hf, Nb, Ta, Mo, Zn, Al, Ga, In, Si and Mn in the total amount of 1 ppm by mass to 0.1% by mass inclusive, with the remainder being 40% by mass or more of Sn.

### CROSS REFERENCE TO PRIOR APPLICATIONS

This application is a U.S. National Phase application under 35 U.S.C. §371 of International Application No. PCT/JP2010/056521, filed on Apr. 12, 2010 and claims benefit of priority to Japanese Patent Application No. 2009-097647, filed on Apr. 14, 2009. The international Application was published in Japanese on Oct. 21, 2010 as WO 2010/119836 under PCT Article 21(2). All of these applications are herein incorporated by reference.

### TECHNICAL FIELD

The invention relates to lead-free solder alloys and solder balls which are used for connecting electronic members, and to electronic members comprising solder bumps.

### BACKGROUND

On an electronic circuit board incorporated in an electronic device, a soldering is used for bonding electronic components to a substrate. Conventionally, a component system comprising tin (Son) and lead (BP) has been widely used for use as a solder alloy for soldering. However, in order to address the environmental problems in recent years or to comply with the RoHS (Restriction of the Use of Certain Hazardous Substances in Electrical and Electronic Equipment) directive in the EU (European Union), solder alloys containing no Pb, i.e., lead-free solder alloys, have been widely developed and put into practical use. Such lead-free solder alloys include the ones containing Sn as a main component, such as Sn—Ag, Sn—Cu, Sn—Ag—Cu, Sn—Sb, Sn—Bi, Sn—Zn-based solder alloys, with other additive elements appropriately added thereto. These various alloys have respective advantages and disadvantages, and are utilized according to application.

In recent years, as a high-density mounting of an electronic component progresses, not only conventional soldering methods such as a hand soldering with the aid of a soldering iron and a flow soldering allowing a junction area between a component and a substrate to go through a solder jet flow but also a reflow soldering using a solder ball or solder paste, has often been used. With respect to the reflow soldering, there have been widely used highly-functional surface-mounting components (hereinafter generally referred to as BGA) such as BGA (Ball Grid Array) using a solder ball, CSP (Chip Size Package), TAB (Tape Automated Bonding), and MCM (Multi Chip Module).

BGA has a semiconductor integrated circuit (IC) incorporated therein, including electrodes generally arranged in a grid pattern on one side thereof. A so-called solder bump, i.e., a clump of solder alloy formed in a shape of a partly-cut-off spherical body, is bonded to each electrode. In order to form such solder bump, there are several methods of formation, among which a method using a solder ball is common. Here, a method for forming a solder bump using a solder ball will be briefly described. First, a viscous flux or solder paste is applied to electrodes of a BGA, and then solder balls are mounted thereon using a mounting device. Then, the BGA on which the solder balls are mounted is heated in a reflow furnace to melt the solder balls, thereby bonding the electrodes to the solder balls, thus forming solder bumps.

As a quality and property required for bonding by means of soldering, it is no doubt that high bonding reliability is imperative, but a post-bonding appearance is also important. That is, it is imperative that the post-bonding solder show a healthy color tone of alloy. In the case that BGAs are shipped out as final products, solder bumps are subjected to visual inspection at a pre-shipment inspection for components, using an image recognition apparatus. Therefore, if color change of the solder bump occurs, an inspection error may be resulted because the apparatus may mistakenly determine that solder bumps are not formed. This is not desirable for the inspection process.

Also see, Japanese Patent No. 3925554, Japanese Patent No. 4144415, and Unexamined Japanese Patent Publication Application No. 2001-200323.

In the case of performing a soldering using the above-mentioned lead free solder alloy containing Sn as a main component, the surface of the solder sometimes turns yellow (yellowing). In the case of BGA, such yellowing poses an obstacle to the inspection by the image recognition apparatus detecting the presence or absence of solder bumps. Further, in the case of BGA, a high-temperature operation test, which is called burn-in test, is performed after forming solder bumps. The burn-in test is a test performed to remove initial failures of BGA components. In the test, for example, it is determined whether any malfunction exists or not in the BGA components while they are put in an atmosphere kept at 125° C. for a long period of time, e.g., 12 hours, thereby determining whether the BGA components have any initial failures or not. After such test, if yellowing occurs in the solder bumps even though the components properly work without malfunction, they cannot be shipped as final products, thus reducing a yield ratio since they are defective products. Also, in the case of the inspection during an automation process, when an image recognition error occurs, it is necessary for an operator to stop the process and intervene in the automation process to check whether solder bumps exist or not, thereby significantly reducing the efficiency of the process.

The present invention has been made in light of the problems described above and it is, therefore, an object of the present invention to provide a lead-free solder alloy, a solder ball and an electronic member comprising a solder bump, wherein the lead-free solder alloy, the solder ball and the solder bump are free from yellowing after a soldering process or a burn-in test.

### SUMMARY

The inventors made an intensive study on a discoloration of a solder surface after soldering, a discoloration of a bump surface on the BGA after formation of a solder bump, and a discoloration of a solder bump surface on the BGA after a burn-in test. As a result, it has been found out that the yellowing of a solder surface after soldering is caused because the surface of a solder alloy is oxidized while melting and solidifying, and thus its resultant surface oxide film is allowed to have such a specific structure that when the surface oxide film reaches a certain specific thickness, the solder surface looks yellow. It has also been found out that the yellowing of a solder bump surface on a BGA after a burn-in test is caused because the bump surface is oxidized and thus its surface oxide film is allowed to ha such a specific structure that when the surface oxide film reaches a certain specific thickness, the solder bump surface looks yellow.

Then, yellowing conditions were examined by adding various elements to solders, and hence specific elements and additive amounts thereof to prevent the yellowing of a solder have been found out, thereby leading to the present invention. Namely, the present invention is summarized as follows:

A lead-free solder alloy according to an example includes Mg as a first additive element, and one or more second additive elements selected from among Be, Sc, Nb, Ta, Mo and Ga, said first and second additive elements being in a total amount of at least 1 ppm but no more than 0.1% by mass, and a remainder containing more than or equal to 40% by mass of Sn.

The lead-free solder alloy according to a second aspect of the present invention is the one in which the lead-free solder alloy is Sn—Ag, Sn—Cu, Sn—Bi, Sn—Sb or Sn—Ag—Cu lead-free solder alloy.

The lead-free solder alloy according to a third aspect of the present invention is the one in which the respective amount of Mg as said first additive element and Be of said second additive elements is at least 1 ppm but no more than 50 ppm by mass.

The lead-free solder alloys according to sixth and seventh aspects of the present invention are the ones in which the lead-free solder alloys area Sn—Ag—Cu solder alloy, and a content of Ag is at least 0.1% but no more than 5% by mass, and a content of Cu is at least 0.01% but no more than 1.5% by mass.

The lead-free solder alloys according to eighth and ninth aspects of the present invention are the ones in which the lead-free solder alloys contain Ni, and a content of Ni is at least 0.005% but no more than 0.5% by mass.

The lead-free solder alloys according to tenth and eleventh aspects of the present invention are the ones in which the lead-free solder alloys contain Ag, Cu and Ni, and a content of Ag is at least 0.8% but no more than 1.5% by mass, and a content of Cu is at least 0.05% but no more than 1.2% by mass, and a content of Ni is at least 0.01% but no more than 0.1% by mass.

The lead-free solder alloys according to twelfth and thirteenth aspects of the present invention are the ones in which the lead-free solder alloys contain Sb, and a content of Sb is at least 0.005% but no more than 1.0% by mass.

Solder balls accordina to fourteenth and fifteenth aspects of the present invention are the ones in which the solder balls are formed from the lead-free solder alloy set forth in the first or third aspect, wherein a spherical diameter thereof is less than or equal to 1 mm.

Electronic members according to sixteenth and seventeenth aspects of the present invention are the ones in which the electronic members comprise a solder bump formed from the lead-free solder alloy set forth in the first or third aspect.

The electronic members according to eighteenth and nineteenth aspects of the present invention are the ones in which the electronic members comprise a solder bump formed from the lead-free solder alloy set forth in the first or third aspect.

According to the invention, it is possible to prevent the occurrence of yellowing on the following surfaces: solder surfaces after soldering; bump surfaces on BGAs after the formation of the solder bumps; and solder bump surfaces BGAs after burn-in test.

Preventing the yellowing can remove an obstacle to the inspection by the image recognition apparatus detecting the presence or absence of solder bumps. Also, the yellowing after the burn-in test can be prevented, thus avoiding a decrease of the yield ratio caused by defective products as they cannot be shipped as final products due to the yellowing. Further, an image recognition error does not occur during the inspection in an automated process, thereby preventing the efficiency of the process from decreasing.

### DETAILED DESCRIPTION

Next is a detailed description of a lead-free solder alloy according to the present invention.

A lead-free solder alloy turns yellow when it does not include any alloy constituents which are more oxidizable than Sn, but includes as large an amount of Sn as, e.g., 40% or more by mass. Therefore, the present invention is aimed at preventing the lead-free solder alloy containing 40% or more by mass of Sn from turning yellowing.

A lead-free solder alloy of the present invention comprises one or more additive elements selected from among Li, Na, K, Ca, Be, Mg, Sc, Y, lanthanides, Ti, Zr, Hf, Nb, Ta, Mo, Zn, Al, Ga, In, Si and Mn in a total amount of 1 ppm to 0.1% by mass. If the total amount of the additive element(s) is less than 1 ppm by mass, the effect of changing a surface color of an oxide film is low, so that the yellowing thereof cannot be prevented. On the other hand, if it exceeds 0.1% by mass, there will occur failures such as decreased solder wettability, poor quality soldering and roughened surfaces of solder bumps. Although the detailed mechanism for preventing the yellowing is still under study, it is presumed that compounding oxide(s) of the additive element(s) relative to a Sn oxide film on the surface causes the surface oxide film to turn from crystalline to either microcrystal or microcrystal and amorphous, thus causing a change in optical property of the surface oxide film, to thereby prevent the surface color change and the resultant yellowing even if the surface is oxidized to the same thickness. Accordingly, it is desirable that the additive element(s) exist(s) in the lead-free solder alloy not as an oxide inclusion but as a metal element.

There are a lot of elements which are more oxidizable than Sn. Among them, adding one or more elements selected from among Li, Na, K, Ca, Be, Mg, Sc, Y, lanthanides, Ti, Zr, Hf, Nb, Ta, Mo, Zn, Al, Ga, In, Si and Mn to the solder alloy, enables the anti-yellowing effect to be fully achieved.

For the lead-free solder alloys containing a sufficient amount of elements which are more easily oxidized than Sn, such as Sn—Zn based solder alloy and etc., there hardly occurs the yellowing. Therefore, the anti-yellowing effect can he more effectively achieved by adding the above additive element(s) to an alloy system containing element(s) which is (are) less oxidizable than Sn, such as Sn—Ag based solder alloy, Sn—Cu based solder alloy, Sn—Bi based solder alloy, Sn—Sb based solder alloy and Sn—Ag—Cu based solder alloy.

With respect to Be, Mg and Ca of the additive elements described above, an additive amount of each element is preferably more than or equal to 1 ppm by mass and less than or equal to 50 ppm by mass. If each additive amount is less than 1 ppm by mass, the anti-yellowing effect is insufficient, and if it exceeds 50 ppm by mass, a surface oxide film after the formation of solder bumps becomes hard, thereby increasing a possibility that its hardness poses an obstacle to soldering in a later process. Adding these elements has a large effect of allowing the surface oxide film to turn into a mixture of microcrystal substances and amorphous ones, and further an increase in thickness of the oxide film due to the burn-in test can be suppressed.

Regarding Zn, Al, Ga, In, Si and Mn selected from among the additive elements described above, an additive amount of each element is preferably more than or equal to 1 ppm by mass and less than or equal to 10 ppm by mass. If each additive amount is less than 1 ppm by mass, the anti-yellowing effect is insufficient, and If it exceeds 10 ppm by mass, the surface oxide film after the formation of the solder bumps becomes hard, thereby increasing a possibility that its hardness poses an obstacle to soldering in the later process or the solder bumps are not properly formed due to the decrease of solder wettability. Also, if it exceeds 8 ppm by mass, a surface asperity after the formation of the solder bumps becomes larger and the image recognition thus becomes difficult. Therefore, each additive amount is preferably less than or equal to 8 ppm by mass.

An analysis of the additive elements in the lead-free solder alloy can be performed by, for example, inductively coupled plasma (ICP) spectrometry method or glow discharge mass spectrometry (GD-MS) method, thus enabling the amount of each additive element to be determined.

In the Sn—Ag—Cu based solder alloy used as a standard lead-free solder alloy among the variety of lead-free alloys described above, if Ag content is more than or equal to 0.1% and less than or equal to 5% by mass and Cu content is more than or equal to 0.01% and less than or equal to 1.5% by mass, drop impact resistance is significantly improved and also other bonding reliabilities such as thermal fatigue property and solder wettability of lead-free alloy are improved. Note that the above-described additive elements with their additive amounts do not cause deterioration of these properties. Incidentally, if the Ag content is less than 0.1% by mass, it may not be preferable due to the decrease of thermal fatigue property of the lead-free alloy in some cases. And, if it exceeds 5% by mass, a lot of oversized Ag₃Sn may be formed in the lead-free solder alloy. As a result, this may cause bonding reliabilities to decrease. More preferably, the Ag content is more than or equal to 0.8% and less than or equal to 1.5% by mass. With respect to the Cu content, if it is less than 0.01% by mass. solder wettability of the lead-free solder alloy may decrease in some cases, and if it is more than 1.5% by mass, the lead-free solder alloy n ay become hard and thus bonding reliabilities may decrease. Still more preferably, it is desirable that the Cu content is more than or equal to 0.05% and less than or equal to 1.0% by mass.

In the Sn—Ag—Cu based lead-free solder alloy, Ni being present in Sn sites can have an effect of suppressing a growth of an intermetallic compound formed on a boundary face between the lead-free solder alloy and an electrode. As a result, bonding reliabilities such as drop impact resistance are significantly improved. Particularly, if Ni content is more than or equal to 0.005% and less than or equal to 0.5% by mass, the effect of enhancing the bonding reliabilities becomes larger. If it is less than 0.005% by mass, the effect may hardly appear in tE some cases. If it is more than 0.5% by mass, bonding reliabilities may decrease due to the hardened lead-free solder alloy. More preferably, the Ni content is more than or equal to 0.01 and less than or equal to 0.1% by mass. The above-mentioned additive elements with their additive amounts do not cause deterioration of these properties.

In the Sn—Ag—Cu lead-free solder alloy, Sb being present in Sn sites can disperse therein, thereby having an effect of improving anti-crack-growth property inside the solder alloy. As a result, its thermal fatigue property is improved. In particular, if Sb content is more than or equal to 0.005% and less than or equal to 1.0% by mass, the effect of improving the thermal fatigue property is significantly large. if it is less than 0.005% by mass, the effect may hardly appear in some cases. Moreover, if it is more than 1.0% by mass, the bonding reliabilities decrease due to the hardened lead-free solder alloy. More preferably, the Sb content is more than or equal to 0.02% and less than or equal to 0.5% by mass. The above-mentioned additive elements with their additive amounts do not cause deterioration of these properties.

Generally, compositions of the elements described above can be measured and identified by for example ICP or GD-MS method.

The lead free solder alloy of the present invention can achieve the effects described above in any forms of the solder alloys such as the ones by a flow solder, a reflow solder and a solder wire which are generally used in the industry. Further, it can also achieve them in the forms of a cream solder including solder powder and a solder ball. Particularly for a solder ball whose spherical diameter is less than or equal to 1 mm and which is used for a fine pitch package connection, it is effective to use the lead-free solder alloys of the present invention. Therefore, an electronic member comprising solder bumps formed using these solder alloys can prevent the yellowing in the burn-in test.

When forming the lead-free solder alloys or solder balls, it is desirable to put them in a non-oxidizing atmosphere such as a vacuum atmosphere or an inert gas atmosphere.

Methods of manufacturing a solder ball from the lead-free solder alloy may include, for example, wire cutting method and in-air granulation method. According to the wire cutting method, a melted lead-free solder alloy ingot is drawn out into wire, and then the wire is cut to a predetermined length, followed by melting each cut wire in oil, thus spherically shaping the same utilizing a surface tension to thereby manufacture a solder ball. Also, according to the in-air granulation method, a melted lead-free solder alloy is jetted through a fine orifice together with vibration into a vacuum atmosphere or a gas atmosphere, and then allowing the waves generated by this vibration to cut the melted alloy to be spherically shaped by its surface tension, thereby manufacturing a solder ball.

Methods for manufacturing a solder bump using the lead-free solder alloy of the present invention generally include a screen printing method and a solder ball method. According to the screen printing method, after finely powdering the lead-free solder alloy using for example atomization method, the fine powders are mixed with a flux to make a paste, and then a predetermined amount of the paste is applied to the electrode by squeezing the paste using a metal mask, and then, a reflow is executed to the electrode to form a solder bump. Also, according to the solder ball method, the solder balls are arranged on the electrodes coated with a flux, and then a reflow is executed thereto to form solder bumps.

The effect of the invention will be described more specifically below with examples.

### EXAMPLES

### Example 1

Respective pure metals were weighed so as to be adjusted to the contents shown in Tables 1 to 5, and then lead-free solder alloys were manufactured from a main component and the weighed pure metals of additive elements of the present invention by high-frequency melting method in a graphite crucible. A composition analysis of the produced lead-free solder alloy was performed by ICP emission spectrometry, ICP-MS or GD-MS, Using each lead-free solder alloy thus produced, solder balls whose diameters were 300 μm were manufactured by the in-air granulation method.

A printed circuit board on which solder balls were to be mounted had a size of 40×30×1 (mm), and a pitch between electrodes was 0.5 mm Also, the board had a bare Cu electrode or a Cu/Ni/Au laminated electrode formed by an electrode surface treatment in which the Cu electrode is plated with Ni and Au. The solder balls on the board were reflowed to make solder bumps. A water-soluble flux was used as a flux. Also, a reflow temperature was 30° C. higher than the melting temperature (liquidus line) of the solder alloy.

The board on which solder bumps were formed was put in a furnace kept at 150° C. for 15 hours in the atmosphere. After it was taken out of the furnace, it was visually checked whether surfaces of the solder bumps turned yellow or not. With respect to the yellowing, when almost no sign of yellowing was observed, it is indicated by a double-circular mark. When the yellowing was observed but image recognition was available, it is indicated by a single-circular mark. When the significant yellowing was observed, it is indicated by across mark. As to solder wettability, when the number of incompletely wetted electrodes after reflowing the board was less than or equal to 0.01%, it is indicated by a double-circular mark. A single-circular mark represents a result in which the corresponding number was greater than 0.01% and less than or equal to 0.1%. When the corresponding number was greater than 0.1% and less than or equal to 1%, it is indicated by a triangular mark. When it exceeded 1%, it is indicated by a cross mark.

With respect to an electric component, a CSP (Chip-Scale Package) having 0.5 mm pitch, 324 pins of pads and 10×10 mm size was used as an evaluation sample on which solder balls were mounted for evaluation of drop impact resistance. The surfaces of the electrodes on the CSP were Cu. Also, a printed circuit board having a 132×77×1 (mm) size and elect odes whose surfaces were treated with Cu-OSP (Cu-Organic Solderbility Preservatives) was used. At first, solder balls were mounted on the CSP and then the CSP was reflowed, thereby forming solder bumps. After that, the CSP was mounted on the printed circuit board. A water-soluble flux was used as a flux. Also, a temperature of the reflow was 30° C. higher than the melting temperature of the solder alloy. The component thus mounted is daisy chained, and it was thus possible to determine a fracture by measuring a resistance of a circuit. The evaluation of drop impact resistance was performed by a method based on JESD 22-B111 of JEDEC standard. In this evaluation, the fracture was defined based on the number of times of dropping at the time when a resistance became twice as large as an initial resistance while monitoring the resistance of the electronic member every time it was dropped. When the properties are the same or better than those of a solder alloy made of only main components, this is indicated by a double-circular mark. A single-circular mark represents a result in which a degrading ratio of the properties with respect to those of the only-main-component solder alloy was greater than 0% and less than or equal to 10%. When a degrading ratio of the properties with respect to those of the only-main-component solder alloy exceeded 10%, this is indicated by a cross mark.

Thermal fatigue property was evaluated as follows: The CSP of the same type as the one used in the drop impact test was used. Also, the printed circuit board having a size of 50×50×0.7 (mm) and electrodes whose surfaces were treated with Cu-OSP was used. Mounted components were subjected to hourly-based temperature cycles in which the mounted components were kept at −40° C. for 20 minutes and at 125° C. for 20 minutes. It is deemed that the fracture occurred at the time when a resistance of a daisy-chained circuit became twice as large as a resistance which was measured before the evaluation. Thermal fatigue property was evaluated based on the number of repetitions of high temperature and low temperature until the fracture occurred (the number of times of the temperature cycle). When the properties are the same or better than those of a solder alloy made of only main components, this is indicated by a double-circular mark. A single-circular mark represents a result in which a degrading ratio of the properties with respect to those of the only-main-component solder alloy was greater than 0% and less than or equal to 10%. When a degrading ratio of the properties with respect to those of the only-main-component solder alloy exceeded 10%, this is indicated by a cross mark.

The results of comparison in terms of solder wettability, drop impact resistance and thermal fatigue between the ones according to the present invention and those composed of the main components only were shown in Tables 1 to 5.

As shown in Tables 1 to 5, according to the present invention, prevention of the yellowing is realized without deteriorating solder wettability, drop impact resistance and thermal fatigue.

TABLE 1

| | Main | Additive element 1 | | Additive element 2 | | Yellowing | | Solder wettability | | | | |
|---|---|---|---|---|---|---|---|---|---|---|---|---|
| | components | | Additive | | Additive | | | | | Drop | | |
| No. | of solder alloy | Element | amount | | amount | Cu | Cu/ | Cu | Cu/ | impact | Thermal | |
| | (mass %) | | (mass ppm) | Element | (mass ppm) | electrode | Ni/Au | electrode | Ni/Au | resistance | fatigue | Remarks |
| 1 | Sn | Li | 0 | | | X | X | ⊚ | ⊚ | ⊚ | ⊚ | Comparative |
| | | | | | | | | | | | | example |
| 2 | | | 0.5 | | | X | X | ⊚ | ⊚ | ⊚ | ⊚ | Comparative |
| | | | | | | | | | | | | example |
| 3 | | | 1 | | | ◯ | ◯ | ⊚ | ⊚ | ⊚ | ⊚ | Reference |
| | | | | | | | | | | | | example |
| 4 | | | 1000 | | | ⊚ | ⊚ | ◯ | ◯ | ⊚ | ⊚ | Reference |
| | | | | | | | | | | | | example |
| 5 | | | 1100 | | | ⊚ | ⊚ | X | X | ◯ | ◯ | Comparative |
| | | | | | | | | | | | | example |
| 6 | Sn—3.5Ag | Na | 0 | | | X | X | ⊚ | ⊚ | ⊚ | ⊚ | Comparative |
| | | | | | | | | | | | | example |
| 7 | | | 0.5 | | | X | X | ⊚ | ⊚ | ⊚ | ⊚ | Comparative |
| | | | | | | | | | | | | example |
| 8 | | | 1 | | | ◯ | ◯ | ⊚ | ⊚ | ⊚ | ⊚ | Reference |
| | | | | | | | | | | | | example |
| 9 | | | 1000 | | | ⊚ | ⊚ | ◯ | ◯ | ⊚ | ⊚ | Reference |
| | | | | | | | | | | | | example |
| 10 | | | 1100 | | | ◯ | ◯ | X | X | ◯ | ◯ | Comparative |
| | | | | | | | | | | | | example |
| 11 | Sn—0.7Cu | K | 0 | | | X | X | ⊚ | ⊚ | ⊚ | ⊚ | Comparative |
| | | | | | | | | | | | | example |
| 12 | | | 0.5 | | | X | X | ⊚ | ⊚ | ⊚ | ⊚ | Comparative |
| | | | | | | | | | | | | example |
| 13 | | | 1 | | | ◯ | ◯ | ⊚ | ⊚ | ⊚ | ⊚ | Reference |
| | | | | | | | | | | | | example |
| 14 | | | 1000 | | | ⊚ | ⊚ | ◯ | ◯ | ⊚ | ⊚ | Reference |
| | | | | | | | | | | | | example |
| 15 | | | 1100 | | | ⊚ | ⊚ | X | X | ◯ | ◯ | Comparative |
| | | | | | | | | | | | | example |
| 16 | Sn—58Bi | Y | 0 | | | X | X | ⊚ | ⊚ | ⊚ | ⊚ | Comparative |
| | | | | | | | | | | | | example |
| 17 | | | 0.5 | | | X | X | ⊚ | ⊚ | ⊚ | ⊚ | Comparative |
| | | | | | | | | | | | | example |
| 18 | | | 1 | | | ◯ | ◯ | ⊚ | ⊚ | ⊚ | ⊚ | Reference |
| | | | | | | | | | | | | example |
| 19 | | | 1000 | | | ⊚ | ⊚ | ◯ | ◯ | ⊚ | ⊚ | Reference |
| | | | | | | | | | | | | example |
| 20 | | | 1100 | | | ⊚ | ⊚ | X | X | ◯ | ◯ | Comparative |
| | | | | | | | | | | | | example |
| 21 | Sn—7Sb | La | 0 | Ce | 0 | X | X | ⊚ | ⊚ | ⊚ | ⊚ | Comparative |
| | | | | | | | | | | | | example |
| 22 | | | 0.3 | | 0.2 | X | X | ⊚ | ⊚ | ⊚ | ⊚ | Comparative |
| | | | | | | | | | | | | example |
| 23 | | | 0.5 | | 0.5 | ◯ | ◯ | ⊚ | ⊚ | ⊚ | ⊚ | Reference |
| | | | | | | | | | | | | example |
| 24 | | | 500 | | 500 | ⊚ | ⊚ | ◯ | ◯ | ⊚ | ⊚ | Reference |
| | | | | | | | | | | | | example |
| 25 | | | 550 | | 550 | ⊚ | ⊚ | X | X | ◯ | ◯ | Comparative |
| | | | | | | | | | | | | example |
| 26 | Sn—3.0Ag—0.5Cu | Ti | 0 | | | X | X | ⊚ | ⊚ | ⊚ | ⊚ | Comparativ |
| | | | | | | | | | | | | example |
| 27 | | | 0.5 | | | X | X | ⊚ | ⊚ | ⊚ | ⊚ | Comparative |
| | | | | | | | | | | | | example |
| 28 | | | 1 | | | ◯ | ◯ | ⊚ | ⊚ | ⊚ | ⊚ | Reference |
| | | | | | | | | | | | | example |
| 29 | | | 1000 | | | ⊚ | ⊚ | ◯ | ◯ | ⊚ | ⊚ | Reference |
| | | | | | | | | | | | | example |
| 30 | | | 1100 | | | ⊚ | ⊚ | X | X | ◯ | ◯ | Comparative |
| | | | | | | | | | | | | example |
| 31 | Sn—1.0Ag—0.5Cu | Nb | 0 | | | X | X | ⊚ | ⊚ | ⊚ | ⊚ | Comparative |
| | | | | | | | | | | | | example |
| 32 | | | 0.5 | | | X | X | ⊚ | ⊚ | ⊚ | ⊚ | Comparative |
| | | | | | | | | | | | | example |
| 33 | | | 1 | | | ◯ | ◯ | ⊚ | ⊚ | ⊚ | ⊚ | Reference |
| | | | | | | | | | | | | example |
| 34 | | | 1000 | | | ⊚ | ⊚ | ◯ | ◯ | ⊚ | ⊚ | Reference |
| | | | | | | | | | | | | example |
| 35 | | | 1100 | | | ⊚ | ⊚ | X | X | ◯ | ◯ | Comparative |
| | | | | | | | | | | | | example |
| 36 | Sn—0.3Ag—0.7Cu | Mo | 0 | | | X | X | ⊚ | ⊚ | ⊚ | ⊚ | Comparative |
| | | | | | | | | | | | | example |
| 37 | | | 0.5 | | | X | X | ⊚ | ⊚ | ⊚ | ⊚ | Comparative |
| | | | | | | | | | | | | example |
| 38 | | | 1 | | | ◯ | ◯ | ⊚ | ⊚ | ⊚ | ⊚ | Reference |
| | | | | | | | | | | | | example |
| 39 | | | 1000 | | | ⊚ | ⊚ | ◯ | ◯ | ⊚ | ⊚ | Reference |
| | | | | | | | | | | | | example |
| 40 | | | 1100 | | | ⊚ | ⊚ | X | X | ◯ | ◯ | Comparative |
| | | | | | | | | | | | | example |

TABLE 2

| | | Additive element 1 | | Additive element 2 | | Yellowing | | Solder wettability | | | | |
|---|---|---|---|---|---|---|---|---|---|---|---|---|
| | Main | | Additive | | Additive | | | | | Drop | | |
| | components | | amount | | amount | Cu | | Cu | | impact | | |
| | of solder alloy | Ele- | (mass | Ele- | (mass | elec- | Cu/ | elec- | Cu/ | resis- | Thermal | |
| No. | (mass %) | ment | ppm) | ment | ppm) | trode | Ni/Au | trode | Ni/Au | tance | fatigue | Remarks |
| 41 | Sn—1.2Ag—0.5Cu—0.05Ni | Be | 0 | | | X | X | ⊚ | ⊚ | ⊚ | ⊚ | Comparative |
| | | | | | | | | | | | | example |
| 42 | | | 0.5 | | | X | X | ⊚ | ⊚ | ⊚ | ⊚ | Comparative |
| | | | | | | | | | | | | example |
| 43 | | | 1 | | | ◯ | ◯ | ⊚ | ⊚ | ⊚ | ⊚ | Reference |
| | | | | | | | | | | | | example |
| 44 | | | 10 | | | ⊚ | ⊚ | ⊚ | ⊚ | ⊚ | ⊚ | Reference |
| | | | | | | | | | | | | example |
| 45 | | | 50 | | | ⊚ | ⊚ | ⊚ | ⊚ | ⊚ | ⊚ | Reference |
| | | | | | | | | | | | | example |
| 46 | | | 70 | | | ⊚ | ⊚ | ◯ | ◯ | ⊚ | ⊚ | Reference |
| | | | | | | | | | | | | example |
| 47 | | Mg | 0.5 | | | X | X | ⊚ | ⊚ | ⊚ | ⊚ | Comparative |
| | | | | | | | | | | | | example |
| 48 | | | 1 | | | ◯ | ◯ | ⊚ | ⊚ | ⊚ | ⊚ | Reference |
| | | | | | | | | | | | | example |
| 49 | | | 10 | | | ⊚ | ⊚ | ⊚ | ⊚ | ⊚ | ⊚ | Reference |
| | | | | | | | | | | | | example |
| 50 | | | 50 | | | ⊚ | ⊚ | ⊚ | ⊚ | ⊚ | ⊚ | Reference |
| | | | | | | | | | | | | example |
| 51 | | | 70 | | | ⊚ | ⊚ | ◯ | ◯ | ⊚ | ⊚ | Reference |
| | | | | | | | | | | | | example |
| 52 | | Ca | 0.5 | | | X | X | ⊚ | ⊚ | ⊚ | ⊚ | Comparative |
| | | | | | | | | | | | | example |
| 53 | | | 1 | | | ◯ | ◯ | ⊚ | ⊚ | ⊚ | ⊚ | Reference |
| | | | | | | | | | | | | example |
| 54 | | | 10 | | | ⊚ | ⊚ | ⊚ | ⊚ | ⊚ | ⊚ | Reference |
| | | | | | | | | | | | | example |
| 55 | | | 50 | | | ⊚ | ⊚ | ⊚ | ⊚ | ⊚ | ⊚ | Reference |
| | | | | | | | | | | | | example |
| 56 | | | 70 | | | ⊚ | ⊚ | ◯ | ◯ | ⊚ | ⊚ | Reference |
| | | | | | | | | | | | | example |
| 57 | | Mg | 0.5 | Be | 0.5 | ◯ | ◯ | ⊚ | ⊚ | ⊚ | ⊚ | Working |
| | | | | | | | | | | | | Example |
| 58 | | | 25 | | 25 | ⊚ | ⊚ | ⊚ | ⊚ | ⊚ | ⊚ | Working |
| | | | | | | | | | | | | Example |
| 59 | | | 50 | | 50 | ⊚ | ⊚ | ⊚ | ⊚ | ⊚ | ⊚ | Working |
| | | | | | | | | | | | | Example |
| 60 | | | 55 | | 55 | ⊚ | ⊚ | ◯ | ◯ | ⊚ | ⊚ | Working |
| | | | | | | | | | | | | Example |

TABLE 3

| | | Additive element 1 | | Additive element 2 | | Yellowing | | Solder wettability | | | | |
|---|---|---|---|---|---|---|---|---|---|---|---|---|
| | Main | | Additive | | Additive | | | | | | | |
| | components | | amount | | amount | Cu | | Cu | | Drop | | |
| | of solder alloy | Ele- | (mass | Ele- | (mass | elec- | Cu/ | elec- | Cu/ | impact | Thermal | |
| No. | (mass %) | ment | ppm) | ment | ppm) | trode | Ni/Au | trode | Ni/Au | resistance | fatigue | Remarks |
| 61 | Sn—1.2Ag—0.5Cu—0.05Ni | Zn | 0.5 | | | X | X | ⊚ | ⊚ | ⊚ | ⊚ | Comparative |
| | | | | | | | | | | | | example |
| 62 | | | 1 | | | ◯ | ◯ | ⊚ | ⊚ | ⊚ | ⊚ | Reference |
| | | | | | | | | | | | | example |
| 63 | | | 10 | | | ◯ | ◯ | ⊚ | ⊚ | ⊚ | ⊚ | Reference |
| | | | | | | | | | | | | example |
| 64 | | | 20 | | | ◯ | ◯ | ◯ | ◯ | ⊚ | ⊚ | Reference |
| | | | | | | | | | | | | example |
| 65 | | Al | 0.5 | | | X | X | ⊚ | ⊚ | ⊚ | ⊚ | Comparative |
| | | | | | | | | | | | | example |
| 66 | | | 1 | | | ◯ | ◯ | ⊚ | ⊚ | ⊚ | ⊚ | Reference |
| | | | | | | | | | | | | example |
| 67 | | | 10 | | | ◯ | ◯ | ⊚ | ⊚ | ⊚ | ⊚ | Reference |
| | | | | | | | | | | | | example |
| 68 | | | 20 | | | ◯ | ◯ | ◯ | ◯ | ⊚ | ⊚ | Reference |
| | | | | | | | | | | | | example |
| 69 | | Ga | 0.5 | | | X | X | ⊚ | ⊚ | ⊚ | ⊚ | Comparative |
| | | | | | | | | | | | | example |
| 70 | | | 1 | | | ◯ | ◯ | ⊚ | ⊚ | ⊚ | ⊚ | Reference |
| | | | | | | | | | | | | example |
| 71 | | | 10 | | | ◯ | ◯ | ⊚ | ⊚ | ⊚ | ⊚ | Reference |
| | | | | | | | | | | | | example |
| 72 | | | 20 | | | ◯ | ◯ | ◯ | ◯ | ⊚ | ⊚ | Reference |
| | | | | | | | | | | | | example |
| 73 | | In | 0.5 | | | X | X | ⊚ | ⊚ | ⊚ | ⊚ | Comparative |
| | | | | | | | | | | | | example |
| 74 | | | 1 | | | ◯ | ◯ | ⊚ | ⊚ | ⊚ | ⊚ | Reference |
| | | | | | | | | | | | | example |
| 75 | | | 10 | | | ◯ | ◯ | ⊚ | ⊚ | ⊚ | ⊚ | Reference |
| | | | | | | | | | | | | example |
| 76 | | | 20 | | | ◯ | ◯ | ◯ | ◯ | ⊚ | ⊚ | Reference |
| | | | | | | | | | | | | example |
| 77 | | Si | 0.5 | | | X | X | ⊚ | ⊚ | ⊚ | ⊚ | Comparative |
| | | | | | | | | | | | | example |
| 78 | | | 1 | | | ◯ | ◯ | ⊚ | ⊚ | ⊚ | ⊚ | Reference |
| | | | | | | | | | | | | example |
| 79 | | | 10 | | | ◯ | ◯ | ⊚ | ⊚ | ⊚ | ⊚ | Reference |
| | | | | | | | | | | | | example |
| 80 | | | 20 | | | ◯ | ◯ | ◯ | ◯ | ⊚ | ⊚ | Reference |
| | | | | | | | | | | | | example |
| 81 | | Mn | 0.5 | | | X | X | ⊚ | ⊚ | ⊚ | ⊚ | Comparative |
| | | | | | | | | | | | | example |
| 82 | | | 1 | | | ◯ | ◯ | ⊚ | ⊚ | ⊚ | ⊚ | Reference |
| | | | | | | | | | | | | example |
| 83 | | | 10 | | | ◯ | ◯ | ⊚ | ⊚ | ⊚ | ⊚ | Reference |
| | | | | | | | | | | | | example |
| 84 | | | 20 | | | ◯ | ◯ | ◯ | ◯ | ⊚ | ⊚ | Reference |
| | | | | | | | | | | | | example |

TABLE 4

| | | Additive element 1 | | Additive element 2 | | Yellowing | | Solder wettability | | | | |
|---|---|---|---|---|---|---|---|---|---|---|---|---|
| | Main | | Additive | | Additive | | | | | | | |
| | components | | amount | | amount | Cu | | Cu | | Drop | | |
| | of solder alloy | Ele- | (mass | Ele- | (mass | elec- | Cu/ | elec- | Cu/ | impact | Thermal | |
| No. | (mass %) | ment | ppm) | ment | ppm) | trode | Ni/Au | trode | Ni/Au | resistance | fatigue | Remarks |
| 85 | Sn—1.2Ag—0.7Cu—0.01Ni | Be | 0 | | | X | X | ⊚ | ⊚ | ⊚ | ⊚ | Comparative |
| | | | | | | | | | | | | example |
| 86 | | | 0.5 | | | ◯ | ◯ | ⊚ | ⊚ | ⊚ | ⊚ | Comparative |
| | | | | | | | | | | | | example |
| 87 | | | 1 | | | ◯ | ◯ | ⊚ | ⊚ | ⊚ | ⊚ | Reference |
| | | | | | | | | | | | | example |
| 88 | | | 10 | | | ⊚ | ⊚ | ⊚ | ⊚ | ⊚ | ⊚ | Reference |
| | | | | | | | | | | | | example |
| 89 | | | 50 | | | ⊚ | ⊚ | ⊚ | ⊚ | ⊚ | ⊚ | Reference |
| | | | | | | | | | | | | example |
| 90 | | | 70 | | | ⊚ | ⊚ | ◯ | ◯ | ⊚ | ⊚ | Reference |
| | | | | | | | | | | | | example |
| 91 | | Mg | 0.5 | | | X | X | ⊚ | ⊚ | ⊚ | ⊚ | Comparative |
| | | | | | | | | | | | | example |
| 92 | | | 1 | | | ◯ | ◯ | ⊚ | ⊚ | ⊚ | ⊚ | Reference |
| | | | | | | | | | | | | example |
| 93 | | | 10 | | | ⊚ | ⊚ | ⊚ | ⊚ | ⊚ | ⊚ | Reference |
| | | | | | | | | | | | | example |
| 94 | | | 50 | | | ⊚ | ⊚ | ⊚ | ⊚ | ⊚ | ⊚ | Reference |
| | | | | | | | | | | | | example |
| 95 | | | 70 | | | ⊚ | ⊚ | ◯ | ◯ | ⊚ | ⊚ | Reference |
| | | | | | | | | | | | | example |
| 96 | | Ca | 0.5 | | | X | X | ⊚ | ⊚ | ⊚ | ⊚ | Comparative |
| | | | | | | | | | | | | example |
| 97 | | | 1 | | | ◯ | ◯ | ⊚ | ⊚ | ⊚ | ⊚ | Reference |
| | | | | | | | | | | | | example |
| 98 | | | 10 | | | ⊚ | ⊚ | ⊚ | ⊚ | ⊚ | ⊚ | Reference |
| | | | | | | | | | | | | example |
| 99 | | | 50 | | | ⊚ | ⊚ | ⊚ | ⊚ | ⊚ | ⊚ | Reference |
| | | | | | | | | | | | | example |
| 100 | | | 70 | | | ⊚ | ⊚ | ◯ | ◯ | ⊚ | ⊚ | Comparative |
| | | | | | | | | | | | | example |
| 101 | Sn—1.2Ag—1.0Cu—0.05Ni | Be | 0 | | | X | X | ⊚ | ⊚ | ⊚ | ⊚ | Comparative |
| | | | | | | | | | | | | example |
| 102 | | | 0.5 | | | X | X | ⊚ | ⊚ | ⊚ | ⊚ | Reference |
| | | | | | | | | | | | | example |
| 103 | | | 1 | | | ◯ | ◯ | ⊚ | ⊚ | ⊚ | ⊚ | Reference |
| | | | | | | | | | | | | example |
| 104 | | | 10 | | | ⊚ | ⊚ | ⊚ | ⊚ | ⊚ | ⊚ | Reference |
| | | | | | | | | | | | | example |
| 105 | | | 50 | | | ⊚ | ⊚ | ⊚ | ⊚ | ⊚ | ⊚ | Reference |
| | | | | | | | | | | | | example |
| 106 | | | 70 | | | ⊚ | ⊚ | ◯ | ◯ | ⊚ | ⊚ | Reference |
| | | | | | | | | | | | | example |
| 107 | | Mg | 0.5 | | | X | X | ⊚ | ⊚ | ⊚ | ⊚ | Comparative |
| | | | | | | | | | | | | example |
| 108 | | | 1 | | | ◯ | ◯ | ⊚ | ⊚ | ⊚ | ⊚ | Reference |
| | | | | | | | | | | | | example |
| 109 | | | 10 | | | ⊚ | ⊚ | ⊚ | ⊚ | ⊚ | ⊚ | Reference |
| | | | | | | | | | | | | example |
| 110 | | | 50 | | | ⊚ | ⊚ | ⊚ | ⊚ | ⊚ | ⊚ | Reference |
| | | | | | | | | | | | | example |
| 111 | | | 70 | | | ⊚ | ⊚ | ◯ | ◯ | ⊚ | ⊚ | Reference |
| | | | | | | | | | | | | example |
| 112 | | Ca | 0.5 | | | X | X | ⊚ | ⊚ | ⊚ | ⊚ | Comparative |
| | | | | | | | | | | | | example |
| 113 | | | 1 | | | ◯ | ◯ | ⊚ | ⊚ | ⊚ | ⊚ | Reference |
| | | | | | | | | | | | | example |
| 114 | | | 10 | | | ⊚ | ⊚ | ⊚ | ⊚ | ⊚ | ⊚ | Reference |
| | | | | | | | | | | | | example |
| 115 | | | 50 | | | ⊚ | ⊚ | ⊚ | ⊚ | ⊚ | ⊚ | Reference |
| | | | | | | | | | | | | example |
| 116 | | | 70 | | | ⊚ | ⊚ | ◯ | ◯ | ⊚ | ⊚ | Reference |
| | | | | | | | | | | | | example |
| 117 | | Mg | 0.5 | Be | 0.5 | ◯ | ◯ | ⊚ | ⊚ | ⊚ | ⊚ | Working |
| | | | | | | | | | | | | Example |
| 118 | | | 25 | | 25 | ⊚ | ⊚ | ⊚ | ⊚ | ⊚ | ⊚ | Working |
| | | | | | | | | | | | | Example |
| 119 | | | 50 | | 50 | ⊚ | ⊚ | ⊚ | ⊚ | ⊚ | ⊚ | Working |
| | | | | | | | | | | | | Example |
| 120 | | | 55 | | 55 | ⊚ | ⊚ | ◯ | ◯ | ⊚ | ⊚ | Working |
| | | | | | | | | | | | | Example |

TABLE 5

| | | Additive element 1 | | Additive element 2 | | Yellowing | | Solder wettability | | | | |
|---|---|---|---|---|---|---|---|---|---|---|---|---|
| | Main | | Additive | | Additive | | | | | Drop | | |
| | components | | amount | | amount | Cu | Cu/ | Cu | Cu/ | impact | Ther- | |
| | of solder alloy | Ele- | (mass | Ele- | (mass- | elec- | Ni/ | elec- | Ni/ | resis- | mal | Re- |
| No. | (mass %) | ment | ppm) | ment | ppm) | trode | Au | trode | Au | tance | fatigue | marks |
| 121 | Sn—1.2Ag—0.5Cu—0.01Ni—0.3Sb | Mg | 0 | Be | 0 | X | X | ⊚ | ⊚ | ⊚ | ⊚ | Com- |
| | | | | | | | | | | | | parison |
| | | | | | | | | | | | | example |
| 122 | | | 0.5 | | 0.5 | ◯ | ◯ | ⊚ | ⊚ | ⊚ | ⊚ | Working |
| | | | | | | | | | | | | example |
| 123 | | | 25 | | 25 | ⊚ | ⊚ | ⊚ | ⊚ | ⊚ | ⊚ | Working |
| | | | | | | | | | | | | example |
| 124 | | | 50 | | 50 | ⊚ | ⊚ | ⊚ | ⊚ | ⊚ | ⊚ | Working |
| | | | | | | | | | | | | example |
| 125 | | | 55 | | 55 | ⊚ | ⊚ | ◯ | ◯ | ⊚ | ⊚ | Working |
| | | | | | | | | | | | | example |

### Example 2

A solder paste was produced using components shown in Table 6, and then solder bumps were formed using the same printed circuit board and CSP as the reference example 1 by the screen printing method, and then the same evaluation as the reference example 1 was performed. The results were also shown in Table 6.

As shown in Table 6, according to the present invention, prevention of the yellowing is realized without deteriorating solder wettability, drop impact resistance and thermal fatigue.

TABLE 6

| | | Additive element 1 | | Additive element 2 | | Yellowing | | Solder wettability | | | | |
|---|---|---|---|---|---|---|---|---|---|---|---|---|
| | Main | | Additive | | Additive | | | | | | | |
| | components | | amount | | amount | Cu | | Cu | | Drop | | |
| | of solder alloy | Ele- | (mass | Ele- | (mass | elec- | Cu/ | elec- | Cu/ | impact | Thermal | |
| No. | (mass %) | ment | ppm) | ment | ppm) | trode | Ni/Au | trode | Ni/Au | resistance | fatigue | Remarks |
| 126 | Sn—1.2Ag—0.5Cu—0.05Ni | Mn | 0 | | | X | X | ⊚ | ⊚ | ⊚ | ⊚ | Comparative |
| | | | | | | | | | | | | example |
| 127 | | | 0.5 | | | X | X | ⊚ | ⊚ | ⊚ | ⊚ | Comparative |
| | | | | | | | | | | | | example |
| 128 | | | 1 | | | ◯ | ◯ | ⊚ | ⊚ | ⊚ | ⊚ | Reference |
| | | | | | | | | | | | | example |
| 129 | | | 10 | | | ◯ | ◯ | ⊚ | ⊚ | ⊚ | ⊚ | Reference |
| | | | | | | | | | | | | example |
| 130 | | | 20 | | | ◯ | ◯ | ◯ | ◯ | ⊚ | ⊚ | Reference |
| | | | | | | | | | | | | example |
| 131 | Sn—1.2Ag—1.0Cu—0.05Ni | Mg | 0 | | | X | X | ⊚ | ⊚ | ⊚ | ⊚ | Comparative |
| | | | | | | | | | | | | example |
| 132 | | | 0.5 | | | X | X | ⊚ | ⊚ | ⊚ | ⊚ | Comparative |
| | | | | | | | | | | | | example |
| 133 | | | 1 | | | ◯ | ◯ | ⊚ | ⊚ | ⊚ | ⊚ | Reference |
| | | | | | | | | | | | | example |
| 134 | | | 10 | | | ⊚ | ⊚ | ⊚ | ⊚ | ⊚ | ⊚ | Reference |
| | | | | | | | | | | | | example |
| 135 | | | 50 | | | ⊚ | ⊚ | ⊚ | ⊚ | ⊚ | ⊚ | Reference |
| | | | | | | | | | | | | example |
| 136 | | | 70 | | | ⊚ | ⊚ | ◯ | ◯ | ⊚ | ⊚ | Reference |
| | | | | | | | | | | | | example |

1. A lead-free solder alloy comprising:
Mg as a first additive element, and one or more second additive elements selected from among Be, Sc, Nb, Ta, Mo and Ga, said first and second additive elements being in a total amount of at least 1 ppm but no more than 0.1% by mass, and
a remainder containing more than or equal to 40% by mass of Sn.

2. The lead-free solder alloy according to claim 1, wherein the lead-free solder alloy is Sn—Ag, Sn—Cu, Sn—Bi, Sn—Sb or Sn—Ag—Cu lead-free solder alloy.

3. The lead-free solder alloy according to claim 1, wherein the respective amount of Mg as said first additive element and Be of said second additive elements is at least 1 ppm but no more than 50 ppm by mass.

4. (canceled)

5. (canceled)

6. The lead-free solder alloy according to claim 1, wherein the lead-free solder alloy is a Sn—Ag—Cu solder alloy, and a content of Ag is at least 0.1% but no more than 5% by mass, and a content of Cu is at least 0.01% but no more than 1.5% by mass.

7. The lead-flee solder alloy according to claim 3, wherein the lead-free solder alloy is a Sn—Ag—Cu solder alloy, and a content of Ag is at least 0.1% but no more than 5% by mass, and a content of Cu is at least 0.01% but no more than 1.5% by mass.

8. The lead-free solder alloy according to claim 6, wherein the lead-free solder alloy contains Ni, and a content of Ni is at least 0.005% but no more than 0.5% by mass.

9. The lead-free solder alloy according to claim 7, wherein the lead-free solder alloy contains Ni, and a content of Ni is at least 0.005% but no more than 0.5% by mass.

10. The lead-free solder alloy according to claim 6, wherein the lead-free solder alloy contains Ag, Cu and Ni, and a content of Ag is at least 0.8% but no more than 1.5% by mass, and a content of Cu is at least 0.05% but no more than 1.2% by mass, and a content of Ni is at least 0.01% but no more than 0.1% by mass.

11. The lead-free solder alloy according to claim 7, wherein the lead-free solder alloy contains Ag, Cu and Ni, and a content of Ag is at least 0.8% but no more than 1.5% by mass, and a content of Cu is at least 0.05% but no more than 1.2% by mass, and a content of Ni is at least 0.01% but no more than 0.1% by mass.

12. The lead-free solder alloy according to claim 6, wherein the lead-free solder alloy contains Sb, and a content of Sb is at least 0.005% but no more than 1.0% by mass.

13. The lead-free solder alloy according to claim 7, wherein the lead-free solder alloy contains Sb, and a content of Sb is at least 0.005% but no more than 1.0% by mass.

14. A solder ball formed from the lead-free solder alloy according to claim 1, wherein a spherical diameter thereof is less than or equal to 1 mm.

15. A solder ball formed from the lead-free solder alloy according to claim 3, wherein a spherical diameter thereof is less than or equal to 1 mm.

16. An electronic member comprising a solder bump formed from the lead-free solder alloy according to claim 1.

17. An electronic member comprising a solder bump formed from the lead-free solder alloy according to claim 3.

18. An electronic member comprising a solder bump formed using the solder ball according to claim 14.

19. An electronic member comprising a solder bump formed using the solder ball according to claim 15.
